(19) United States
(12) Patent Application Publication
(10) Pub. No.: US 2026/0362669 A1
(43) Pub. Date: Nov. 12, 2026

(54) STACKED TRANSISTOR MEMORY CELLS AND METHODS OF FORMING THE SAME

(71) Applicant: Taiwan Semiconductor Manufacturing Co., Ltd., Hsinchu (TW)

(72) Inventors: Chia Chen Lee, Taipei (TW); Wei-Chen Chu, Taichung (TW); Chia-Tien Wu, Taichung (TW); Ken-Hsien Hsieh, Taipei (TW); Shu-Yun Ku, Hsinchu (TW)

(21) Appl. No.: 19/734,918

(22) Filed: Jul. 8, 2026

Related U.S. Application Data
(63) Continuation of application No. 19/047,932, filed on Feb. 7, 2025.
(60) Provisional application No. 63/700,863, filed on Sep. 30, 2024.

(51) Int. Cl. H10B 10/00

(52) U.S. Cl. CPC H10B 10/125

(57) ABSTRACT

A memory device includes a first lower epitaxial source/drain region adjacent a second lower epitaxial source/drain region; a first lower gate electrode adjacent a first side of the first lower epitaxial source/drain region; a second lower gate electrode adjacent a second side of the second lower epitaxial source/drain region, wherein the second side is opposite the first side; a dielectric layer under the first lower epitaxial source/drain region, the second lower epitaxial source/drain region, the first lower gate electrode, and the second lower gate electrode; a first butted contact within the dielectric layer, wherein the first butted contact electrically connects the first lower epitaxial source/drain region to the second lower gate electrode; and a second butted contact within the dielectric layer, wherein the second butted contact electrically connects the second lower epitaxial source/drain region to the first lower gate electrode.

### PRIORITY CLAIM AND CROSS-REFERENCE

This application is a continuation of U.S. Patent Application No. 19/047,932, filed on Feb. 7, 2025, which claims the benefit of the following provisionally filed U.S. Patent application: Application No. 63/700,863, filed on Sep. 30, 2024, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional view of example Complementary Field-Effect Transistors (CFETs), in accordance with some embodiments.

FIGS. 2-8 are various views of intermediate stages in the manufacturing of CFETs, in accordance with some embodiments.

FIG. 9 illustrates a schematic of a SRAM cell, in accordance with some embodiments.

FIG. 10 illustrates a three-dimensional view of a SRAM cell, in accordance with some embodiments.

FIGS. 11A, 11B, 12A, 12B, 13A, 13B, 14A, 14B, 15A, 15B, 16A, 16B, 17A, 17B, 18A, 18B, 19A, and 19B illustrate plan views and cross-sectional views of intermediate stages in the formation of butted contacts, in accordance with some embodiments.

FIGS. 20A, 20B, 21A, 21B, 22A, 22B, 23A, 23B, 24A, and 24B illustrate plan views and cross-sectional views of intermediate stages in the formation of butted contacts, in accordance with some embodiments.

FIGS. 25A, 25B, 26A, and 26B illustrate plan views and cross-sectional views of intermediate stages in the formation of butted contacts, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) structure and methods of forming the same are provided. According to various embodiments, CFETs are interconnected to form memory cells, such as static random-access memory (SRAM) cells. The CFETs include vertically stacked complementary nanostructure-FETs, and the SRAM cells have a four-transistor footprint, e.g., a footprint of four p-type transistors and four overlying n-type transistors. Methods of forming backside interconnections between CFETs in a memory cell are provided. The embodiments described herein can allow for improved device scaling, improved yield, improved device reliability, and improved device performance.

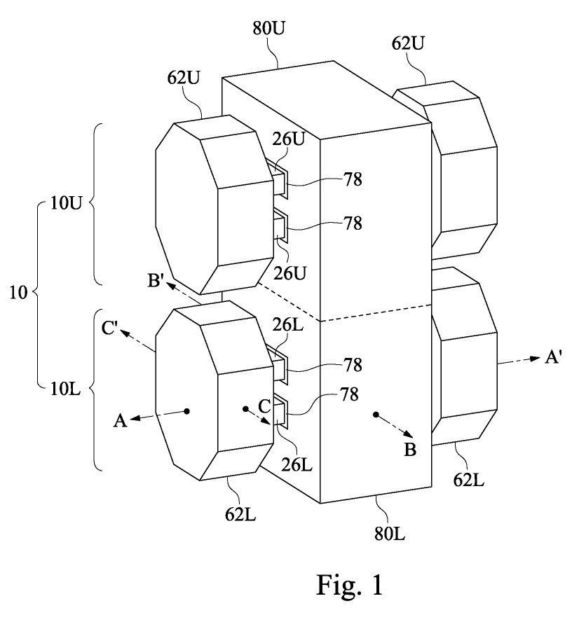

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor 10 includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., FinFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A' is a vertical cross-section that is parallel to a longitudinal axis of the semiconductor nanostructures 26 of a stacking transistor and in a direction of, for example, a current flow between the source/drain regions 62 of the stacking transistor. Cross-section B-B' is a vertical cross-section that is perpendicular to cross-section A-A' and along a longitudinal axis of a gate electrode 80 of the CFET. Cross-section C-C' is a vertical cross-section that is parallel to cross-section B-B' and extends through the source/drain regions 62 of the stacking transistor. Subsequent figures may refer to these reference cross-sections for clarity.

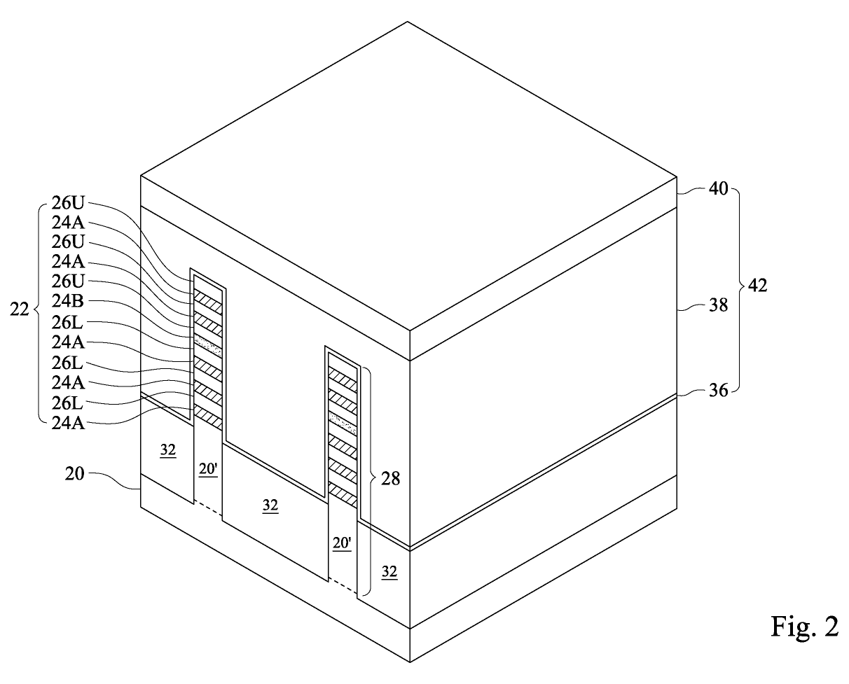

FIGS. 2-8 illustrate the cross-sectional views of intermediate stages in the formation of stacking transistors (as schematically represented in FIG. 1) in accordance with some embodiments. In subsequent discussion, unless specified otherwise, the figures illustrate the vertical cross-sectional views along a similar cross-section as vertical reference cross-section A-A' in FIG. 1. In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strips 20’ (patterned portions of the semiconductor substrate 20, also referred to as semiconductor fins 20') and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, the dummy semiconductor nanostructures 24A are formed of or comprise silicon germanium, the semiconductor layers 26 are formed of silicon, and the dummy semiconductor nanostructures 24B may be formed of germanium or silicon germanium with a higher germanium atomic percentage than the semiconductor nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20', the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

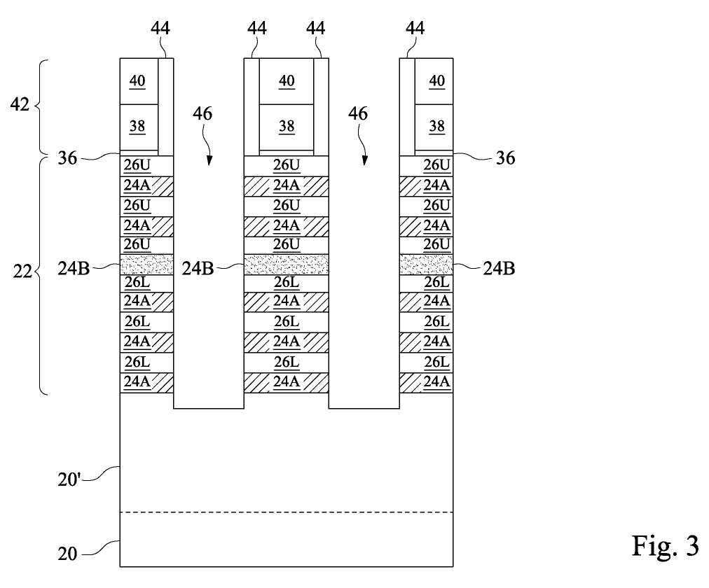

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20’. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

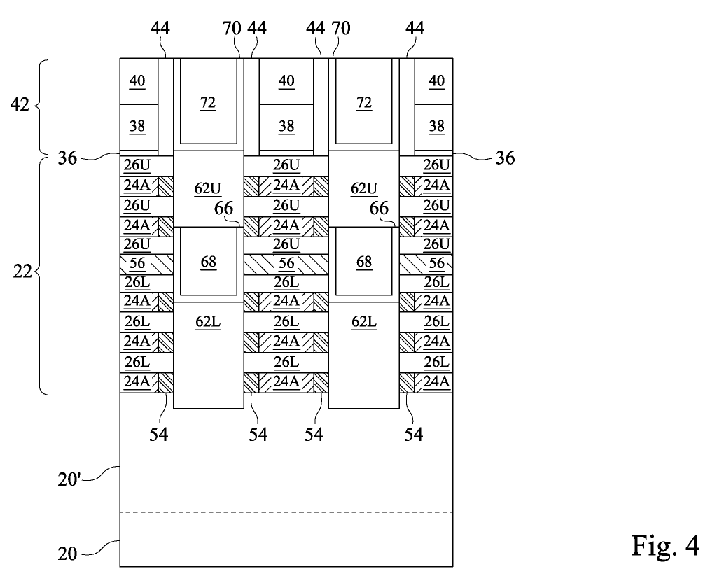

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 24A (thus forming the inner spacers 54) and has portions remaining in between the upper and lower semiconductor nanostructures 26U and 26L (thus forming the dielectric isolation layers 56).

As also illustrated by FIG. 4, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the masks 40 (if present) or the dummy gates 38 are exposed through the second ILD 72. In the illustrated embodiment, the masks 40 remain after the removal process. In other embodiments, the masks 40 are removed such that the top surfaces of the dummy gates 38 are exposed through the second ILD 72.

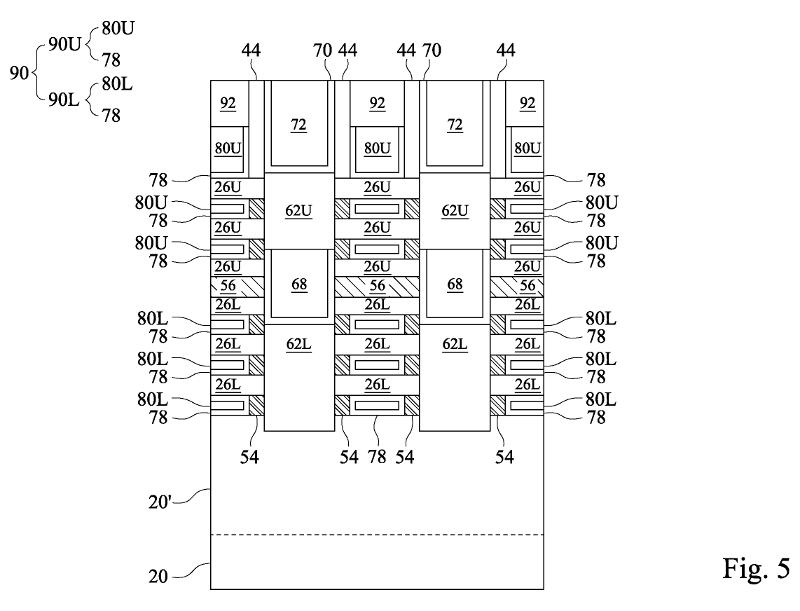

FIG. 5 illustrates a replacement gate process to replace the dummy gate stacks 42 and the dummy nanostructures 24A with gate structures 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor strips 20'; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate stack” 90 or a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor strip 20'.

As also shown in FIG. 5, gate masks 92 are formed over the gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

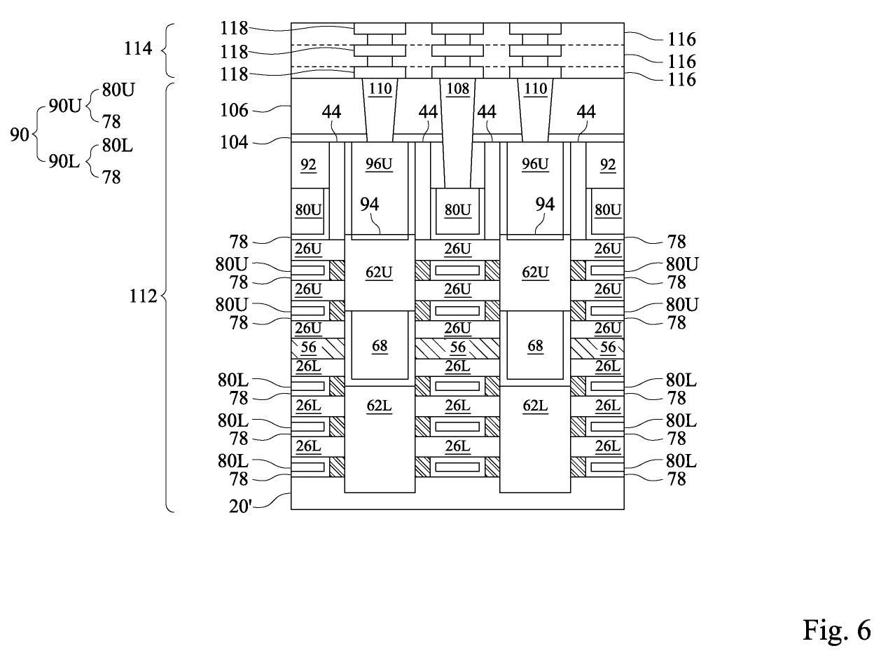

In FIG. 6, metal-semiconductor alloy regions 94 and upper source/drain contacts 96U are formed through the second ILD 72 to electrically couple to the upper epitaxial source/drain regions 62U. As an example to form the upper source/drain contacts 96U, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the upper source/drain contacts 96U in the openings. In some embodiments, a planarization process such as a CMP, an etch-back process, combinations thereof, or the like is utilized. After the planarization process, the top surfaces of the gate spacers 44, the second ILD 72, and the upper source/drain contacts 96U are substantially coplanar (within process variations).

Optionally, metal-semiconductor alloy regions 94 are formed at the interfaces between the source/drain regions 62 and the upper source/drain contacts 96U. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the upper source/drain contacts 96U by depositing a metal in the openings for the upper source/drain contacts 96U and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the upper source/drain contacts 96U, such as from surfaces of the metal-semiconductor alloy regions 94. The material(s) of the upper source/drain contacts 96U can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon nitride, silicon oxynitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, upper gate contacts 108 and upper source/drain vias 110 are formed to contact the upper gate electrodes 80U and the upper source/drain contacts 96U, respectively. As an example to form the upper gate contacts 108 and the upper source/drain vias 110, openings for the upper gate contacts 108 and the upper source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the upper gate contacts 108 and the upper source/drain vias 110 in the openings. The upper gate contacts 108 and the upper source/drain vias 110 may be formed in distinct processes, or may be formed in the same process. Although shown as being formed in the same cross-section, it should be appreciated that each of the upper gate contacts 108 and the upper source/drain vias 110 may be formed in different cross-sections, which may avoid shorting of the contacts. The resulting structure may be considered a memory device, memory structure, or the like, and may be referred to as device layer 112, in some cases. Additional processing is performed on the device layer 112, described below.

Still referring to FIG. 6, a front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers. The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias.

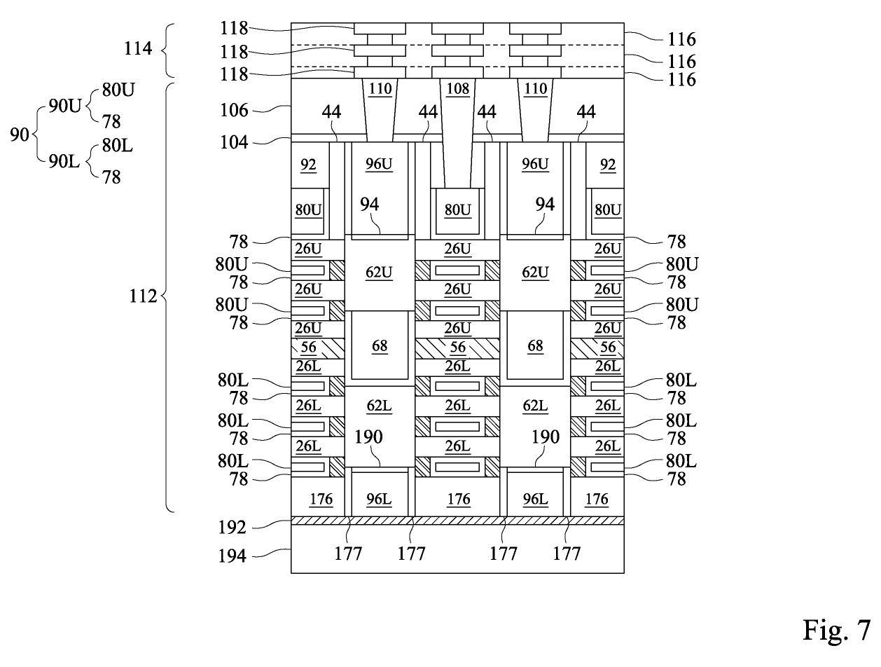

In FIG. 7, lower source/drain contacts 96L are formed to electrically couple to the lower epitaxial source/drain regions 62L, in accordance with some embodiments. In some embodiments, the semiconductor strips 20’ are optionally removed and replaced with dielectric regions 176. Replacing the semiconductor strips 20’ with the dielectric regions 176 can help reduce the parasitic capacitance and/or the leakage current of the resulting nanostructure-FETs, thereby improving their performance. The dielectric regions 176 may be formed of a low-k dielectric material, a high-k dielectric material, combinations thereof, or the like, which may be formed by thermal oxidation process, a deposition process, or the like. In some embodiments, the dielectric regions 176 are formed using techniques and materials similar to those described previously for the first ILD 68. Other formation techniques or materials are possible.

As an example to form the dielectric regions 176, the semiconductor strips 20’ are removed to form recesses. The semiconductor strips 20’ may be removed using acceptable photolithography and etching techniques, such as using an etching process that is selective to the semiconductor strips 20’ (e.g., etches the material of the semiconductor strips 20’ at a faster rate than the material of the STI regions 32). One or more dielectric material(s) may then be formed in the recesses. The dielectric material(s) may be conformally formed in the recesses and on the back-sides of the STI regions 32. In some embodiments, the dielectric material(s) include a liner layer of silicon nitride and a fill layer of silicon oxide. After the dielectric material(s) are deposited, a removal process is applied to remove excess dielectric material(s) over the STI regions 32. In some embodiments, a planarization process such as a chemical mechanical polish (CMP), an etch-back process, combinations thereof, or the like may be utilized. The dielectric material(s), when planarized, have portions left in the recesses (thus forming the dielectric regions 176). After the planarization process, the bottom surfaces of the STI regions 32 and the dielectric regions 176 may be substantially coplanar (within process variations).

Next, lower source/drain contacts 96L are formed for the source/drain regions 62. The lower source/drain contacts 96L may be physically and electrically coupled to the lower epitaxial source/drain regions 62L. As an example to form the lower source/drain contacts 96L, openings for the lower source/drain contacts 96L are formed through the dielectric regions 176. The openings may be formed using acceptable photolithography and etching techniques. In some embodiments, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may comprise cobalt, tungsten, copper, a copper alloy, silver, gold, aluminum, nickel, or the like. A removal process may be performed to remove excess material from the bottom surfaces of the dielectric regions 176. The remaining liner and conductive material form the lower source/drain contacts 96L in the openings. In some embodiments, a planarization process such as a chemical mechanical polish (CMP), an etch-back process, combinations thereof, or the like is utilized. After the planarization process, the bottom surfaces of the dielectric regions 176 and the lower source/drain contacts 96L may be substantially coplanar (within process variations). Optionally, metal-semiconductor alloy regions 190 are formed at the interfaces between the lower epitaxial source/drain regions 62L and the lower source/drain contacts 96L. The metal-semiconductor alloy regions 190 may be similar to the metal-semiconductor alloy regions 94 described previously, and may be formed using similar techniques.

Optionally, contact spacers 177 are formed around the lower source/drain contacts 96L. The contact spacers 177 may be formed by conformally depositing one or more dielectric material(s) in the contact openings for the lower source/drain regions 62L and subsequently etching the dielectric material(s). Acceptable dielectric materials may include silicon nitride, silicon carbonitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dielectric regions 176 (thus forming the contact spacers 177).

In the illustrated embodiment, the lower source/drain contacts 96L are coupled to the lower epitaxial source/drain regions 62L. In some embodiments, some of the lower source/drain contacts 96L are shared source/drain contacts that are coupled to both lower epitaxial source/drain regions 62L and upper epitaxial source/drain regions 62U.

Still referring to FIG. 7, a fourth ILD 194 is deposited over the dielectric regions 176, the lower source/drain contacts 96L, and the contact spacers 177. In some embodiments, the fourth ILD 194 is a flowable film formed by a flowable CVD method, which is subsequently cured. In some embodiments, the fourth ILD 194 is formed of a dielectric material such as PSG, BSG, BPSG, USG, or the like, which may be deposited by any suitable method, such as CVD, PECVD, or the like. Other materials are possible.

In some embodiments, an ESL 192 is formed between the fourth ILD 194 and the dielectric regions 176, the lower source/drain contacts 96L, and the contact spacers 177. The ESL 192 may include a dielectric material having a high etching selectivity to the dielectric material of the fourth ILD 194, such as silicon nitride, silicon oxide, silicon oxynitride, or the like. Other materials are possible.

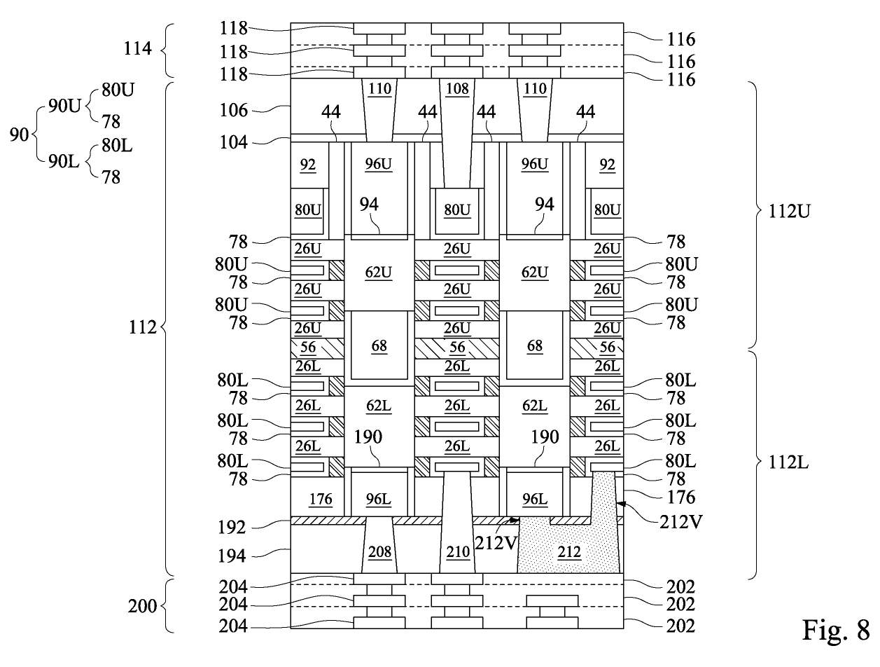

In FIG. 8, lower gate contacts 210, lower source/drain vias 208, and butted contacts 212 are formed through the fourth ILD 194 to contact the lower gate electrodes 80L and/or the lower source/drain contacts 96L. The lower gate contacts 210 extend through the fourth ILD 194, the ESL 192, and the gate dielectrics 78 to physically and electrically couple to lower gate electrodes 80L. The lower source/drain vias 208 extend through the fourth ILD 194 and the ESL 192 to physically and electrically couple to lower source/drain contacts 96L. The butted contacts 212 physically and electrically couple a lower gate electrode 80L and a lower source/drain contact 96L. For example, a butted contact 212 may comprise a via portion similar to a lower gate contact 210 that physically and electrically contacts a lower gate electrode 80L, a via portion similar to a lower source/drain via 208 that physically and electrically contacts a lower source/drain contact 96L, and a line portion extending between the via portions. As shown in FIG. 8, the line portion may be within the fourth ILD 194 and may extend along the ESL 192.While the example butted contact 212 shown in FIG. 8 electrically couples a lower gate electrode 80L to an adjacent lower source/drain contact 96L, in other embodiments a butted contact 212 may electrically couple any lower gate electrode 80L to any lower source/drain contact 96L by suitably configuring the path or dimensions of the line portion of the butted contact 212. Although shown as being formed in the same cross-section, it should be appreciated that each of the gate contacts 210, the source/drain vias 208, and the butted contacts 212 may be formed in different cross-sections.

As an example to form the lower gate contacts 210 and the lower source/drain vias 208, openings for the lower gate contacts 210 are formed through the fourth ILD 194, the ESL 192, the gate dielectrics 78, and the dielectric regions 176, and openings for the lower source/drain vias 208 are formed through the fourth ILD 194 and the ESL 192. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the bottom surface of the fourth ILD 194. The remaining liner and conductive material form the lower gate contacts 210 and the lower source/drain vias 208 in the openings.

The lower gate contacts 210 and the lower source/drain vias 208 may be formed in distinct processes, or may be formed in the same process. In some embodiments, the butted contacts 212 may be formed in a distinct process from the lower gate contacts 210 and/or the lower source/drain vias 208. In other embodiments, the formation of the lower gate contacts 210, the lower source/drain vias 208, and/or the butted contacts 212 may share one or more process steps, such as photolithography steps, etching steps, deposition steps, or other steps. Some embodiments of the formation of butted contacts 212 are described in greater detail below. As shown in FIG. 8, the device layer 112 includes an upper device 112U and a lower device 112L. The upper device 112U comprises, for example, upper semiconductor nanostructures 26U, upper gate structures 90U, and upper epitaxial source/drain regions 62U of the upper nanostructure-FET, and comprises upper gate contacts 108 and upper source/drain vias 110. The lower device 112L comprises, for example, lower semiconductor nanostructures 26L, lower gate structures 90L, and lower epitaxial source/drain regions 62L of the lower nanostructure-FET, and comprises lower gate contacts 210, lower source/drain vias 208, and butted contacts 212.

A back-side interconnect structure 200 is formed on the back side of the device layer 112, in accordance with some embodiments. The back-side interconnect structure 200 includes dielectric layers 202 and layers of conductive features 204 in the dielectric layers 202. The dielectric layers 202 may be formed of dielectric materials such as PSG, BSG, BPSG, USG, silicon oxide, silicon nitride, or the like, or combinations thereof. The dielectric layers 202 may include low-k dielectric layers formed of low-k dielectric materials. The dielectric layers 202 may also include polymer layers. The dielectric layers 202 may be formed using suitable techniques, such as FCVD, CVD, PECVD ALD, or the like. The conductive features 204 may include conductive lines and vias, which may be formed using damascene processes. Conductive features 204 may include metal lines and metal vias, which includes diffusion barriers and a copper containing material over the diffusion barriers. There may also be aluminum pads over and electrically connected to the metal lines and vias.

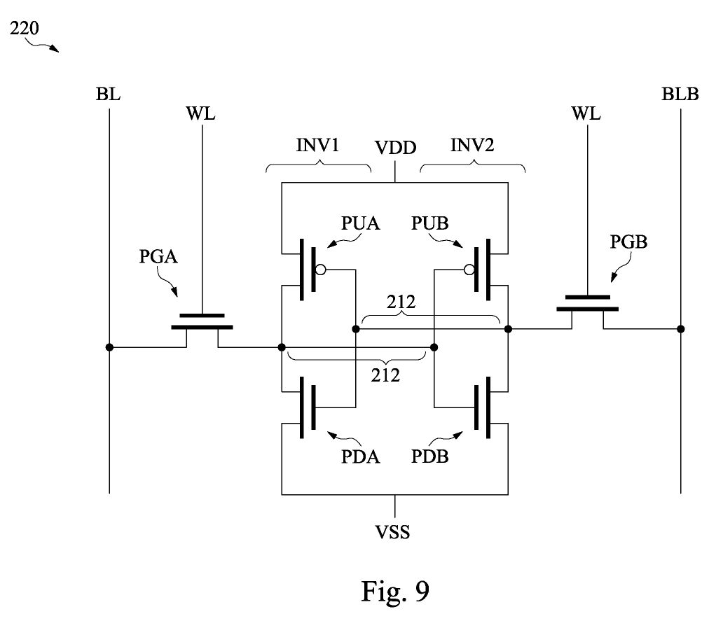

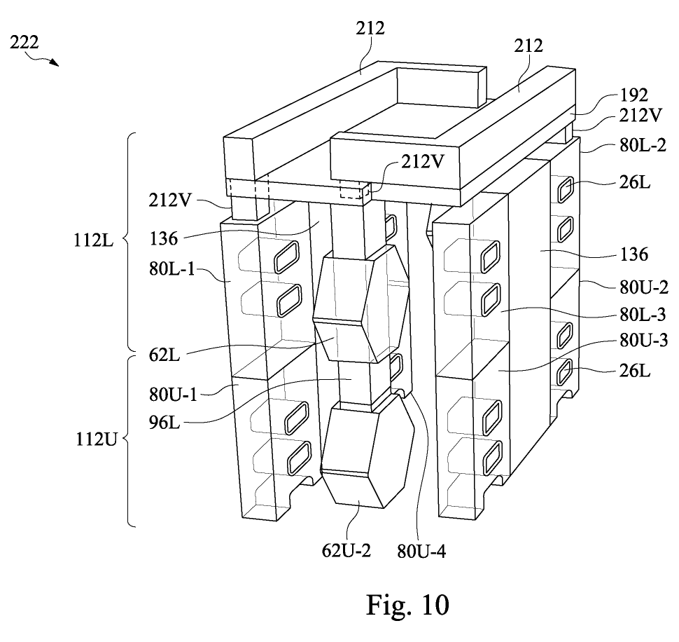

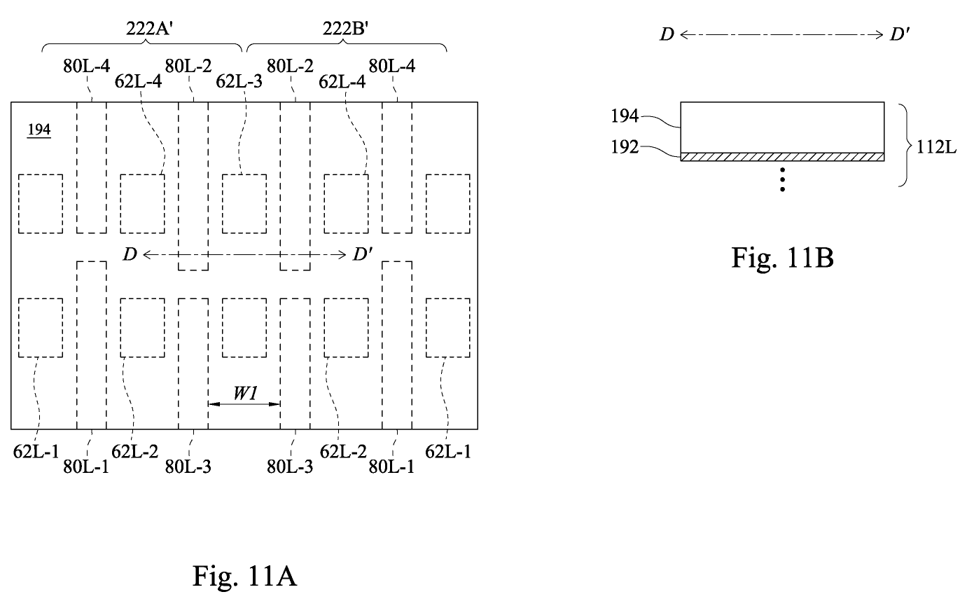

As subsequently described for FIGS. 9 and 10, stacking transistors (e.g., CFETs) may be interconnected to form SRAM cells. A SRAM cell includes two cross-coupled inverters. According to various embodiments, in a SRAM cell, butted contacts 212 are formed that couple lower gate electrodes 80 of lower nanostructure-FETs to corresponding lower source/drain contacts 96L of other lower nanostructure-FETs. In this manner, the butted contacts 212 may be considered “cross-coupling contacts,” in some cases. The output of an inverter (e.g., a lower epitaxial source/drain region 62L) may be connected to the input of another inverter (e.g., a lower gate electrode 80L) using a butted contact 212. The stacking transistors may thus be interconnected to form a SRAM cell. Forming SRAM cells from CFETs may increase memory density due to the CFETs’ vertically stacked nanostructure-FETs. Cross-coupling the inverters with butted contacts 212 may allow the CFETs to be interconnected at a lower interconnect level, improving device density. Example embodiments for forming butted contacts are subsequently described for FIGS. 11A-19B, 20A-24B, and 25A-26B.

FIG. 9 illustrates a schematic of a SRAM cell 220, in accordance with some embodiments. The SRAM cell 220 of FIG. 9 is a six-transistor SRAM cell. The SRAM cell 220 includes a first inverter INV1 and a second inverter INV2 cross-coupled to one another by butted contacts 212. For example, a first butted contact 212 connects the output of the first inverter INV1 to the input of the second inverter INV2, and a second butted contact 212 connects the output of the second inverter INV2 to the input of the first inverter INV1. The first inverter INV1 includes a first pull-up transistor PUA and a first pull-down transistor PDA. The second inverter INV2 includes a second pull-up transistor PUB and a second pull-down transistor PDB. The first pull-up transistor PUA and the second pull-up transistor PUB are each coupled to a supply voltage VDD, while the first pull-down transistor PDA and the second pull-down transistor PDB are each coupled to a reference voltage VSS. The SRAM cell 220 also includes a first pass-gate transistor PGA and a second pass-gate transistor PGB. The first pass-gate transistor PGA controls whether the output of the first inverter INV1 is coupled to a bit line BL and the second pass-gate transistor PGB controls whether the output of the second inverter INV2 is coupled to a bitbar line BLB. The first pass-gate transistor PGA and the second pass-gate transistor PGB are also coupled to and are controlled by a word line WL.

In some embodiments, the SRAM cell 220 includes four n-type transistors and two p-type transistors, which may be formed as n-type nanostructure-FETs and p-type nanostructure-FETs of CFETs. In this manner, the CFETs for a SRAM cell 220 have a four-transistor footprint, e.g., a footprint for four n-type transistors and four p-type transistors. However, only two p-type transistors are used for the SRAM cell 220, and two of the p-type transistors are unused. Lower epitaxial source/drain regions may be omitted from the source/drain recess of the unused p-type regions. The unused p-type transistors may be considered “dummy transistors” in some cases. In some embodiments, the first pull-down transistor PDA and the second pull-down transistor PDB are n-type nanostructure-FETs, and the first pull-up transistor PUA and the second pull-up transistor PUB are p-type nanostructure-FETs. In some embodiments, the first pass-gate transistor PGA and the second pass-gate transistor PGB are n-type nanostructure-FETs.

FIG. 10 is a three-dimensional view of a SRAM cell 222 comprising CFETs, in accordance with some embodiments. The SRAM cell 222 may be similar to the SRAM cell 220 described for FIG. 9, and the CFETs may be similar to the stacked transistors described for FIG. 8. Some features are omitted for illustration clarity. For example, some epitaxial source/drain regions, gate contacts, source/drain vias, and conductive features are not shown. The structure of FIG. 10 is flipped upside-down from the previous figures to more clearly illustrate the butted contacts 212. For example, in FIG. 10, the lower device 112L is shown over the upper device 112U. It should be appreciated that a SRAM cell 222 may also have a similar structure mirrored along a horizontal direction.

In the illustrated embodiment of FIG. 10, the lower nanostructure-FETs of the CFETs (e.g., in the lower device 112L) are p-type devices and the upper nanostructure-FETs of the CFETs (e.g., in the upper device 112U) are n-type devices. Accordingly, the lower nanostructure-FETs include the first pull-up transistor PUA and the second pull-up transistor PUB, while the upper nanostructure-FETs include the first pull-down transistor PDA, the second pull-down transistor PDB, the first pass-gate transistor PGA, and the second pass-gate transistor PGB. Further, the first pull-down transistor PDA and the second pull-down transistor PDB are vertically stacked over the first pull-up transistor PUA and the second pull-up transistor PUB, respectively. Thus, the source/drain regions of the first pull-down transistor PDA and the first pull-up transistor PUA are formed in the same source/drain recesses, and the source/drain regions of the second pull-down transistor PDB and the second pull-up transistor PUB are formed in the same source/drain recesses.

The first pull-down transistor PDA includes first upper source/drain region 62U-1, a second upper source/drain region 62U-2, and a first upper gate electrode 80U-1. The second pull-down transistor PDB includes a third upper source/drain region 62U-3, a fourth upper source/drain region 62U-4, and a second upper gate electrode 80U-2. The first pull-up transistor PUA includes a first lower source/drain region 62L-1, a second lower source/drain region 62L-2, and a first lower gate electrode 80L-1. The second pull-up transistor PUB includes a third lower source/drain region 62L-3, a fourth lower source/drain region 62L-4, and a second lower gate electrode 80L-2. The first pass-gate transistor PGA includes the second upper source/drain region 62U-2, a fifth upper source/drain region 62U-5, and a third upper gate electrode 80U-3. The second pass-gate transistor PGB includes the fourth upper source/drain region 62U-4, a sixth upper source/drain region 62U-6, and a fourth upper gate electrode 80U-4. Some of these features are not visible in FIG. 10, but may be visible in plan views (e.g., top-down views) subsequently described for FIGS. 11A-19A. In a plan view, the first pull-down transistor PDA is diagonally opposite from the second pull-down transistor PDB, the first pull-up transistor PUA is diagonally opposite from the second pull-up transistor PUB, and the first pass-gate transistor PGA is diagonally opposite from the second pass-gate transistor PGB.

Further, the first upper gate electrode 80U-1 of the first pull-down transistor PDA is physically and electrically coupled to the first lower gate electrode 80L-1 of the first pull-up transistor PUA, and the second upper gate electrode 80U-2 of the second pull-down transistor PDB is physically and electrically coupled to the second lower gate electrode 80L-2 of the second pull-up transistor PUB. The first pass-gate transistor PGA and the second pass-gate transistor PBB are vertically stacked over the unused p-type regions. Further, the third upper gate electrode 80U-3 of the first pass-gate transistor PGA is physically and electrically coupled to the third lower gate electrode 80L-3, and the fourth upper gate electrode 80U-4 of the second pass-gate transistor PGB is physically and electrically coupled to the fourth lower gate electrode 80L-4. A source/drain contact 96L is coupled to the second lower source/drain region 62L-2 and to the second upper source/drain region 62U-2, and a source/drain contact 96L is coupled to the fourth lower source/drain region 62L-4 and to the fourth upper source/drain region 62U-4. Adjacent upper gate electrodes 80U and adjacent lower gate electrodes 80L may be physically and electrically isolated by gate isolation regions 136, which may comprise, for example, dielectric or insulating regions. In this manner, the gate isolation regions 136 may “cut” the gate structures.

The butted contacts 212 are coupled to respective lower gate electrodes 80L and to lower source/drain contacts 96L. Each butted contact 212 shown in FIG. 10 is L-shaped in a top-down view, in which one end of the L-shaped contact is coupled to a lower gate electrode 80L by a via portion 212V, and another end of the L-shaped contact is coupled to a lower source/drain contact 96L by a via portion 212V. Butted contacts 212 may have other shapes or dimensions in other embodiments. Similar to the butted contact 212 shown in FIG. 8, the via portions 212V extend through the ESL 192 to make physical and electrical contact to lower gate electrodes 80L and to lower source/drain contacts 96L. The via portions 212V may extend different depths. A line portion (not separately labeled) extends between the via portions 212V. The line portion may extend across a gate isolation region 136. Each SRAM cell 222 has two butted contacts 212, in some embodiments.

FIGS. 11A-19B illustrate intermediate steps in the formation of butted contacts 212, in accordance with some embodiments. FIGS. 11A, 12A, 13A, 14A, 15A, 16A, 17A 18A, and 19A illustrate plan views facing the back side of a structure similar to that shown in FIG. 7. FIGS. 11B, 12B, 13B, 14B, 15B, 16B, 17B, 18B, and 19B illustrate cross-sectional views along a cross-section similar to the cross-section D-D’ indicated in the figures. The cross-sectional views of 11B-19B are flipped upside-down with respect to FIG. 7. For example, FIG. 11B illustrates the fourth ILD 194 over the ESL 192. The various layers and features that may be underneath the ESL 192 are not illustrated in the cross-sectional views of FIGS. 11B-19B.

The process shown in FIGS. 11A-19B includes intermediate steps in the formation of two adjacent SRAM cells 222A and 222B. The regions in which the SRAM cells 222A and 222B are formed are indicated as SRAM regions 222A’ and 222B’, respectively. In other words, each SRAM cell 222 is formed in a corresponding SRAM region 222’. For reference, the lower gate electrodes 80L and lower epitaxial source/drain regions 62L of the SRAM cells 222A-B are indicated by dashed outlines. The lower gate electrodes 80L-1, 80L-2, 80L-3, and 80L-4 and the lower epitaxial source/drain regions 62L-1, 62L-2, 62L-3, and 62L-4 may be similar to those described for FIG. 10 with respect to a single SRAM cell 222. In some embodiments, the techniques described herein allow for butted contacts 212 to be formed across gate electrodes that have a separation width W1 in the range of about 30 nm to about 60 nm, though other widths are possible. The structures shown in FIGS. 11A-19B are for illustrative purposes, and other configurations, other arrangements, other feature dimensions, or other feature shapes are possible. Some features or portions thereof are not shown for clarity.

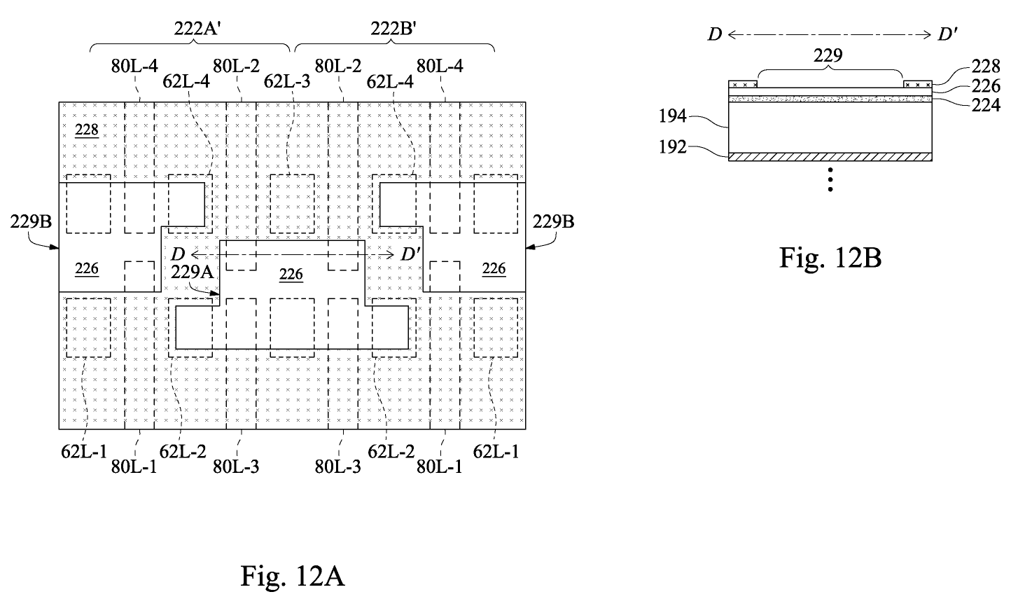

In FIGS. 12A-12B, a sacrificial layer 224, a hard mask 226, and a photoresist 228 are formed over the fourth ILD 194, in accordance with some embodiments. The sacrificial layer 224 may be formed of a dielectric material that is different from the material of the fourth ILD 194. For example, the sacrificial layer 224 may be formed of a material having a high etching selectivity from the etching of the fourth ILD 194, such as, aluminum oxide, aluminum nitride, silicon nitride, silicon oxynitride, silicon oxycarbide, or the like. The sacrificial layer 224 may include other materials, such as a polymer. The sacrificial layer 224 may be formed using any suitable deposition process, such as CVD, ALD, or the like. Other materials or deposition techniques are possible. In some embodiments, the sacrificial layer 224 may be a bottom anti-reflective coating (BARC) layer, an etch stop layer, or the like. In other embodiments, the sacrificial layer 224 is not formed. The hard mask 226 is formed over the sacrificial layer 224. The hard mask 226 may be formed of a dielectric material different from the sacrificial layer 224, such as silicon nitride, silicon oxide, silicon oxynitride, or the like, which may be formed by any suitable deposition process, such as CVD, ALD, or the like. Other materials or deposition techniques are possible.

A photoresist 228 is formed over the hard mask 226 and patterned to form openings 229 that expose the hard mask 226, in accordance with some embodiments. The photoresist 228 may be formed using a suitable technique, such as spin-on or the like. The openings 229 may be patterned in the photoresist 228 using suitable photolithography techniques. The openings 229 are subsequently used to define the butted contacts 212. Some openings 229A extend over the lower gate electrode 80L-2 and the lower epitaxial source/drain region 62L-2 of an SRAM region 222’, and some openings 229B extend over the lower gate electrode 80L-1 and the lower epitaxial source/drain region 62L-4 of an SRAM region 222’. As shown in FIG. 12A, each opening 229 extends across portions of two neighboring SRAM regions 222’. For example, some openings 229A may extend over and between lower gate electrodes 80L-2 of neighboring SRAM regions 222’ and extend over and between lower epitaxial source/drain regions 62L-2 of the same neighboring SRAM regions 222’. Other openings 229B may extend over and between lower gate electrodes 80L-1 of neighboring SRAM regions 222’ and extend over and between lower epitaxial source/drain regions 62L-4 of the same neighboring SRAM regions 222’. The openings 229A are separated from the openings 229B, in some embodiments. In some embodiments, each opening 229 has a “top hat” shape, though the openings 229 may have trapezoidal shapes or other suitable shapes. Forming a top-hat shaped opening 229 rather than an L-shaped opening 229 can allow for more reliable photolithographic patterning, smaller feature size, and improved yield.

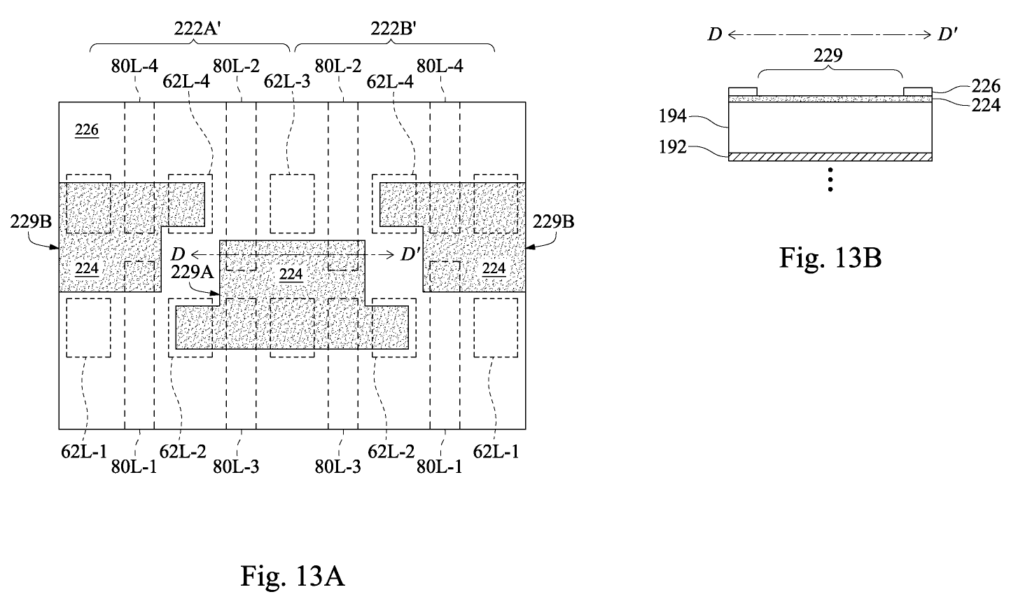

In FIGS. 13A-13B, an etching process is performed to extend the openings 229 through the hard mask 226, in accordance with some embodiments. The etching process may include a suitable wet etching process and/or a suitable dry etching process. The etching process may be anisotropic. After performing the etching process, the openings 229 are transferred to the hard mask 226, and the sacrificial layer 224 is exposed by the openings 229. In this manner, the etching process uses the patterned photoresist 228 as an etch mask. In some embodiments, after etching the hard mask 226, the photoresist 228 is removed using a suitable etching or ashing process.

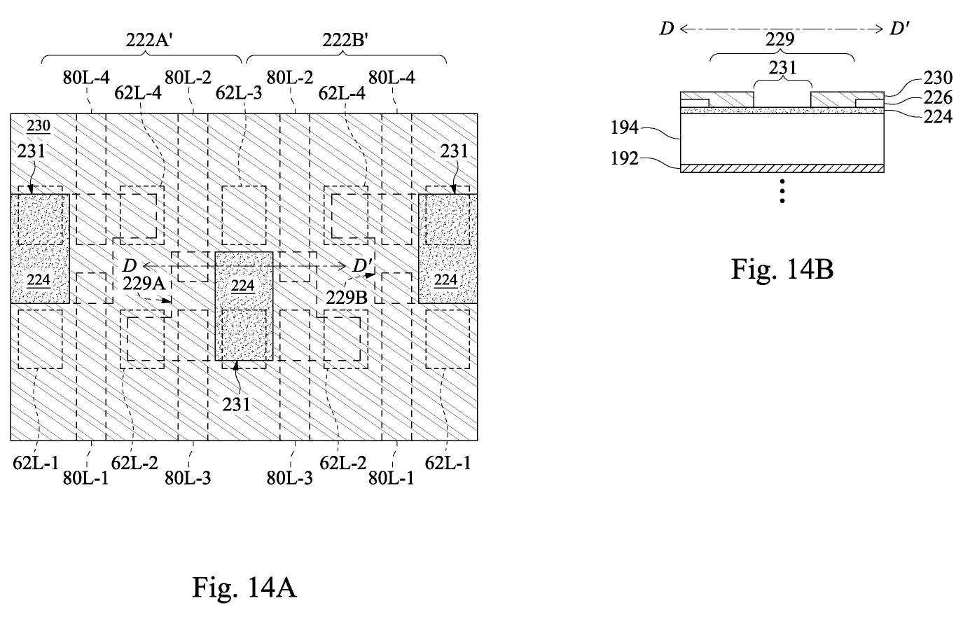

In FIGS. 14A-14B, a photoresist 230 is formed over the hard mask 226 and sacrificial layer 224 and patterned to form openings 231 that expose the sacrificial layer 224, in accordance with some embodiments. The photoresist 230 may be formed using a suitable technique, such as spin-on or the like. The openings 231 may be patterned in the photoresist 230 using suitable photolithography techniques. In some embodiments, each opening 231 is within the perimeter of a corresponding opening 229. Accordingly, some portions of the sacrificial layer 224 within the openings 229 are covered by the photoresist 230, and some portions of the sacrificial layer 224 within the openings 229 are exposed by the openings 231. Each opening 231 defines a separation between opposite regions of the corresponding opening 229, with L-shaped portions of the opening 229 on either side of the opening 231. The portions of the opening 229 on either side of the opening 231 made have other shapes in other embodiments. In some embodiments, the openings 231 are formed between neighboring SRAM regions 222’. For example, openings 231 may be formed between neighboring lower gate electrodes 80L-2 and between neighboring lower gate electrodes 80L-3 of openings 229A, and openings 231 may be formed between neighboring lower gate electrodes 80L-1 and between neighboring lower gate electrodes 80L-4 of openings 229B.

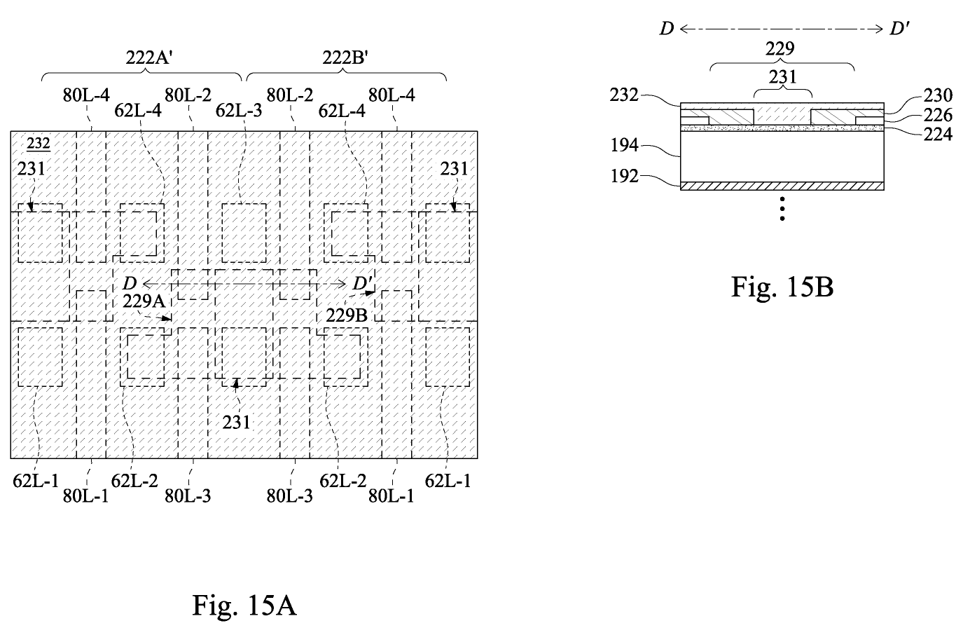

In FIGS. 15A-15B, a mask material 232 is deposited over the patterned photoresist 230 and in the openings 231, in accordance with some embodiments. As shown in FIG. 15B, the mask material 232 may fill the openings 231, may cover exposed surfaces of the sacrificial layer 224, and may cover surfaces of the photoresist 230. The mask material 232 may be a material similar to that of the hard mask 226, in some embodiments. For example, the mask material 232 may be formed of a dielectric material such as silicon nitride, silicon oxide, silicon oxynitride, or the like, which may be formed by any suitable deposition process, such as CVD, FCVD, ALD, or the like. In other embodiments, the mask material 232 and the hard mask 226 may be different materials. For example, in some embodiments, the mask material 232 may comprise polymer, a metal oxide, or another suitable material. The mask material 232 and the sacrificial layer 224 are different materials having an etch selectivity, in some embodiments. As shown in FIG. 15B, the upper portions of the mask material 232 includes lateral portions extending over top surfaces of the photoresist 230. In some cases, a thickness of the lateral portions of the mask material 232 over the photoresist 230 is smaller than a thickness of the photoresist 230 and/or a thickness of the hard mask 226.

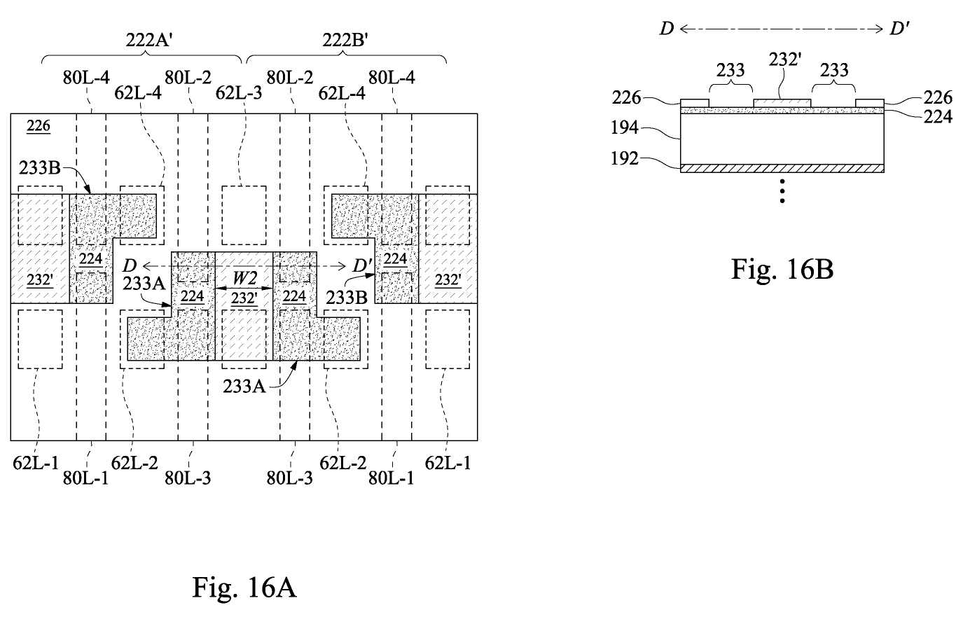

In FIGS. 16A-16B, the photoresist 230 and upper portions of the mask material 232 are removed, in accordance with some embodiments. Lower portions of the mask material 232 remain on the sacrificial layer 224, with these remaining portions forming cut regions 232’ that separate (e.g., “cut”) each opening 229 into two openings 233. Accordingly, in some cases, the mask material 232 may be considered a “cut material” or the like. The openings 233 are used to define the subsequently-formed butted contacts 212. The photoresist 230 and the upper portions of the mask material 232 may be removed using suitable techniques, such as using a peeling process, an ashing process, and/or one or more etching processes. The etching processes may include wet etching process and/or dry etching processes. In some embodiments, the lateral portions of the mask material 232 may be etched to expose top surfaces of the photoresist 230, and then the photoresist 230 may be removed using an ashing process. In some embodiments, the upper portions of the mask material 232 may be removed using a planarization process, such as a CMP process or the like, and the photoresist 230 is then removed using an ashing process. In some embodiments, the photoresist 230 may be fully or partially removed using a wet chemical etch, which results in lift-off of the overlying lateral portions of the mask material 232.

After removing the lateral portions of the mask material 232, the lower portions of the mask material 232 are left remaining to form the cut regions 232’. In other words, the cut regions 232’ are formed from portions of the mask material 232 that were deposited on the sacrificial layer 224 within the openings 231. The cut regions 232’ may have a thickness that is greater than, less than, or about the same as a thickness of the hard mask 226. Each cut region 232’ divides an opening 229 into a pair of openings 233. The openings 233 may have an L-shape, as shown in FIG. 16A, or another shape, such as a triangular shape. The pairs of openings 233 may have a mirror symmetry. As an example, a cut region 232’ divides an opening 229A into a pair of openings 233A. One opening 233A extends over the lower gate electrode 80L-2 and the lower epitaxial source/drain region 62L-2 of a first SRAM region 222A’, and the other opening 233A extends over the lower gate electrode 80L-2 and the lower epitaxial source/drain region 62L-2 of a neighboring SRAM region 222B’. Similarly, a cut region 232’ divides an opening 229B into a pair of openings 233B, with each opening 233B extending over a lower gate electrode 80L-1 and an epitaxial source/drain region 62L-4 of a corresponding SRAM region 222’. In some embodiments, a cut region 232’ may have a width W2 in the range of about 10 nm to about 50 nm, which can allow for larger device density and/or larger butted contacts 212, in some cases. Other widths W2 are possible. Forming the openings 233 by forming cut regions 232’ rather than by patterning the openings 233 directly can allow for a smaller width W2 between openings 233, more reliable formation of the openings 233, more reliable formation of the butted contacts 212, improved yield, and higher device density.

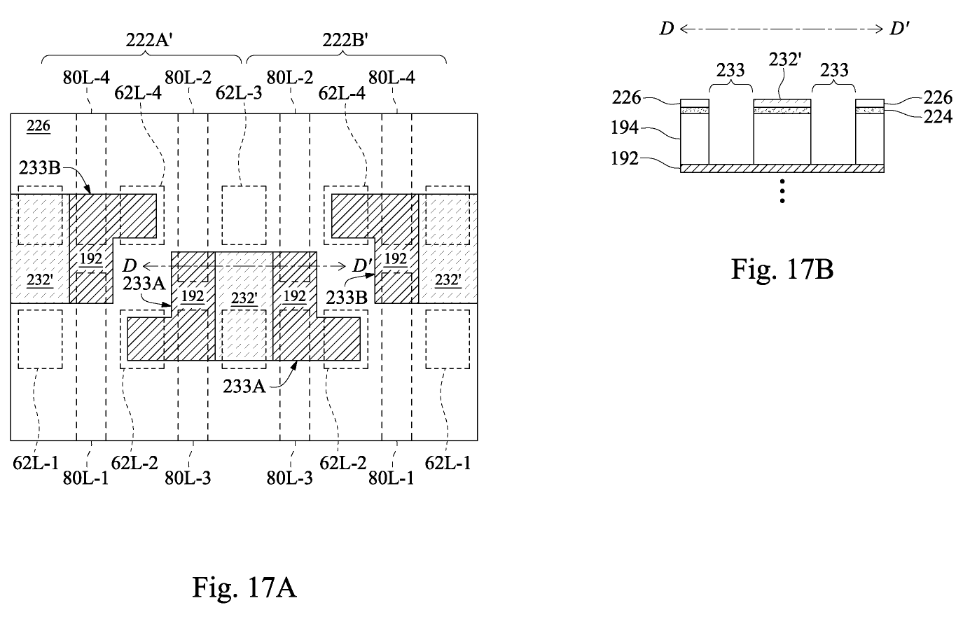

In FIGS. 17A-17B, the openings 233 are extended through the sacrificial layer 224 and the fourth ILD 194, in accordance with some embodiments. The openings 233 may be extended by performing one or more etch processes using the patterned hard mask 226 and the cut regions 232’ as an etch mask. In some embodiments, the openings 233 expose the ESL 192. The etch processes may include one or more suitable wet etching processes or dry etching processes, which may be anisotropic. In some embodiments, the etch process(es) stop on the ESL 192. In some embodiments, one or more timed etch processes are used. In some embodiments, the hard mask 226, the cut regions 232’, and/or the sacrificial layer 224 are removed after etching through the fourth ILD 194.

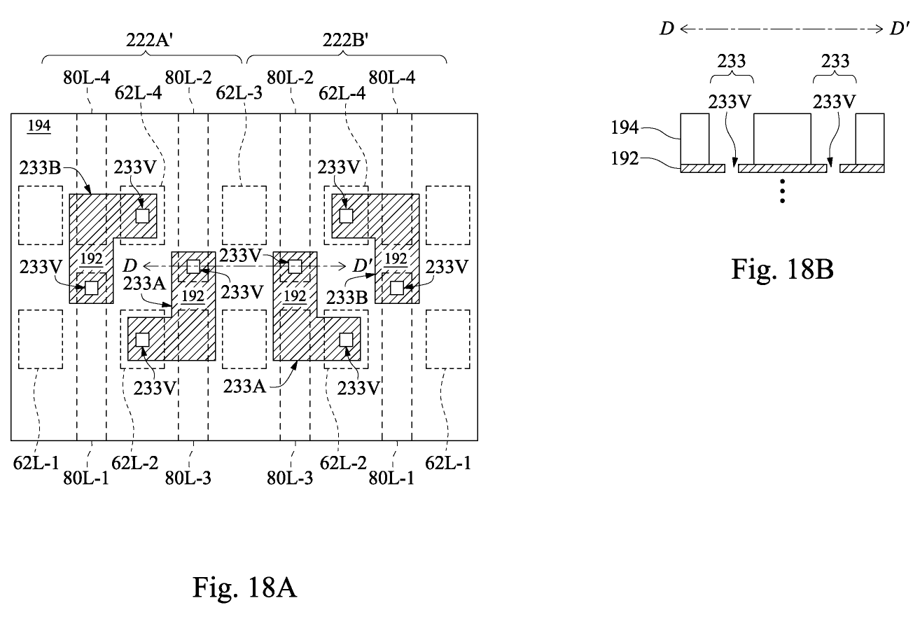

In FIGS. 18A-18B, via openings 233V are formed in the openings 233, in accordance with some embodiments. The via openings 233V may be formed at a different process stage, in other embodiments. The via openings 233V are openings in the ESL 192 within which the via portions 212V of the butted contacts 212 are subsequently formed. In some embodiments, the via openings 233V also extend through other layers, such as through dielectric regions 176, to expose lower gate structure 90L or lower source/drain contacts 96L. In this manner, the via portions 212V of the subsequently formed butted contacts 212 can physically and electrically contact lower gate structure 90L or lower source/drain contacts 96L. For example, via openings 233V may be formed in an opening 233A that expose a lower gate electrode 80L-2 and the lower source/drain contact of a lower epitaxial source/drain region 62L-2, and via openings 233V may be formed in an opening 233B that expose a lower gate electrode 80L-1 and the lower source/drain contact of a lower epitaxial source/drain region 62L-4. The via openings 233V may be formed using suitable photolithography and etching techniques.

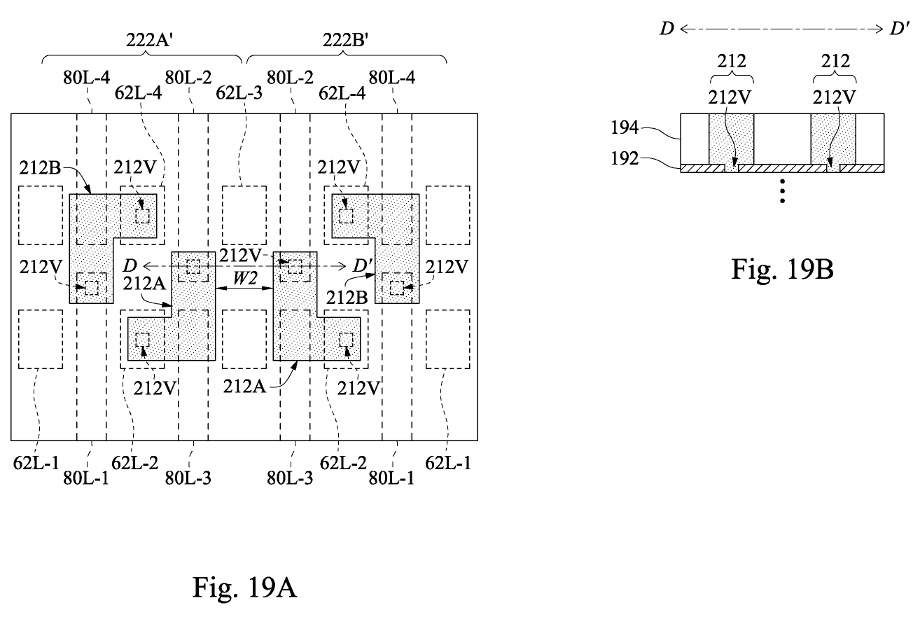

In FIGS. 19A-19B, butted contacts 212 are formed in the openings 233, in accordance with some embodiments. In some embodiments, a liner (not separately illustrated), such as a diffusion barrier layer, an adhesion layer, or the like, and a conductive material are formed in the openings 233. The liner may include titanium, titanium nitride, tantalum, tantalum nitride, or the like. The conductive material may be cobalt, tungsten, copper, a copper alloy, silver, gold, aluminum, nickel, the like, or a combination thereof. In some embodiments, a planarization process such as a CMP, an etch-back process, or the like is performed to remove excess material from top surfaces of the fourth ILD 194. The remaining liner and conductive material form the butted contacts 212 in the openings 233, including via portions 212V in the via openings 233V. After the planarization process, top surfaces of the butted contacts 212 and the fourth ILD 194 are substantially level or coplanar (within process variations). In some embodiments, the liner and/or conductive material are deposited simultaneously for the butted contacts 212, the lower gate contacts 210, and/or the lower source/drain vias 208. Each SRAM cell 222 includes a butted contact 212A and a butted contact 212B. In some embodiments, each butted contact 212A electrically connects a lower gate electrode 80L-2 to a lower epitaxial source/drain region 62L-2, and each butted contact 212B electrically connects a lower gate electrode 80L-1 to a lower epitaxial source/drain region 62L-4. Forming butted contacts 212 using the techniques described herein can allow for smaller butted contacts 212, higher yield, and greater device density.

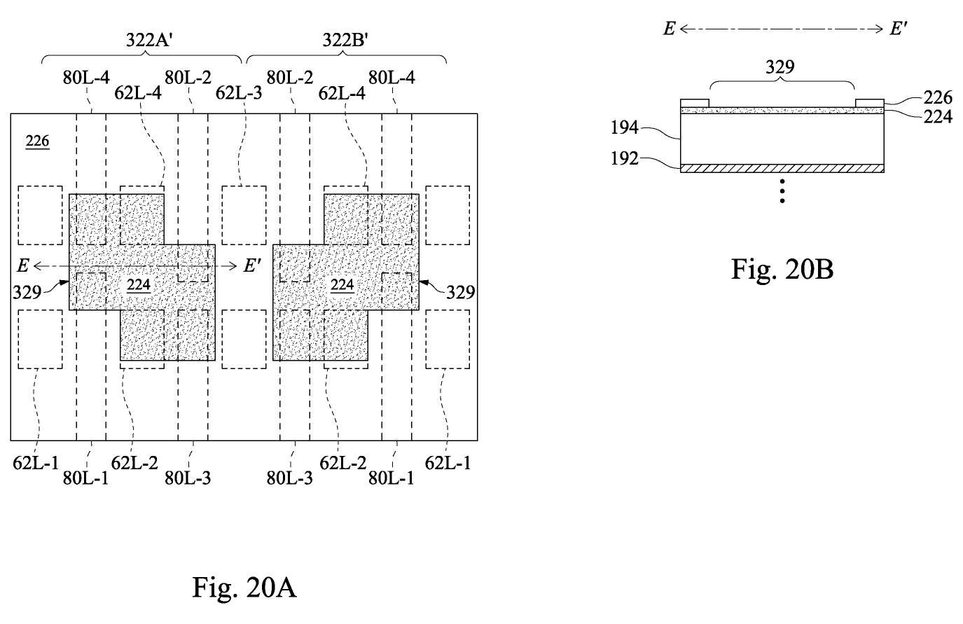

FIGS. 20A through 24B illustrate intermediate steps in the formation of butted contacts 312, in accordance with some embodiments. The butted contacts 312 are similar to the butted contacts 212 described previously for FIGS. 9-10, except that the butted contacts 312 have a triangular shape instead of an L-shape. Additionally, the butted contacts 312 are formed using materials and techniques similar to those described in FIGS. 11A-19B for forming butted contacts 212, except that cut regions 332’ are formed within each SRAM region 322A’/322B’ rather than between adjacent SRAM regions 222A’/222B’. Some of the materials or techniques are similar to those described previously for FIGS. 11A-19B, and some details are not repeated. FIGS. 20A, 21A, 22A, 23A, and 24A illustrate plan views similar to the plan views of FIGS. 11A-19A, and FIGS. 20B, 21B, 22B, 23B, and 24B illustrate cross-sectional views along a cross-section similar to the indicated reference cross-section E-E’.

In FIGS. 20A-20B, a patterned hard mask 226 is formed over the fourth ILD 194, in accordance with some embodiments. The structure of FIGS. 20A-20B may be similar to the structure shown in FIGS. 13A-13B, and may be formed using similar techniques. For example, a sacrificial layer 224 may be formed over the fourth ILD 194, and a hard mask 226 may be formed over the sacrificial layer 224. The sacrificial layer 224 and the hard mask 226 may be similar to those described previously. Openings 329 are then patterned in the hard mask 226 using suitable photolithography and etching techniques. The openings 329 expose the sacrificial layer 224. Each opening is formed in an SRAM region, and each opening 329 partially defines regions where butted contacts 312 are subsequently formed.

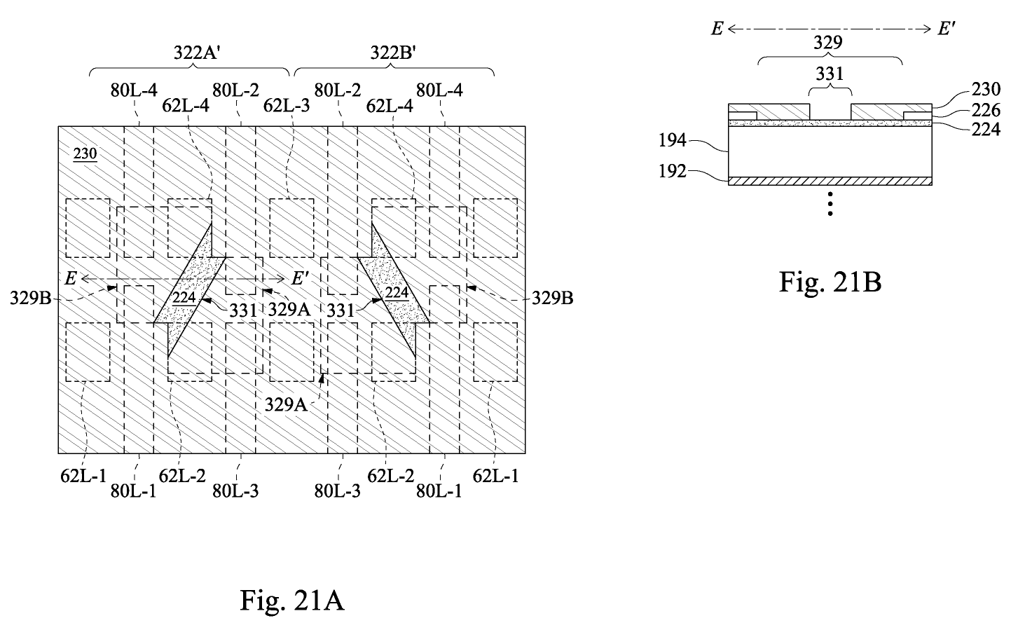

In FIGS. 21A-21B, a photoresist 230 is formed over the hard mask 226 and sacrificial layer 224 and patterned to form openings 331 that expose the sacrificial layer 224, in accordance with some embodiments. The photoresist 230 may be similar to the photoresist 230 described previously for FIGS. 14A-14B, and the openings 331 may be patterned in the photoresist 230 using suitable photolithography techniques, similar to FIGS. 14A-14B. In some embodiments, each opening 331 is within the perimeter of a corresponding opening 329. Accordingly, some portions of the sacrificial layer 224 within the openings 329 are covered by the photoresist 230, and some portions of the sacrificial layer 224 within the openings 229 are exposed by the openings 331. Each opening 331 defines a separation between opposite regions of the corresponding opening 329, with approximately triangular portions of the opening 329 on either side of the opening 331. The portions of the opening 329 on either side of the opening 331 made have other shapes in other embodiments. In some embodiments, the openings 331 are formed within corresponding SRAM regions 322’. In some embodiments, the openings 331 may extend at an angle that is slanted or oblique relative to other features, such as relative to the lower gate electrodes 80L or the semiconductor strips 20’.

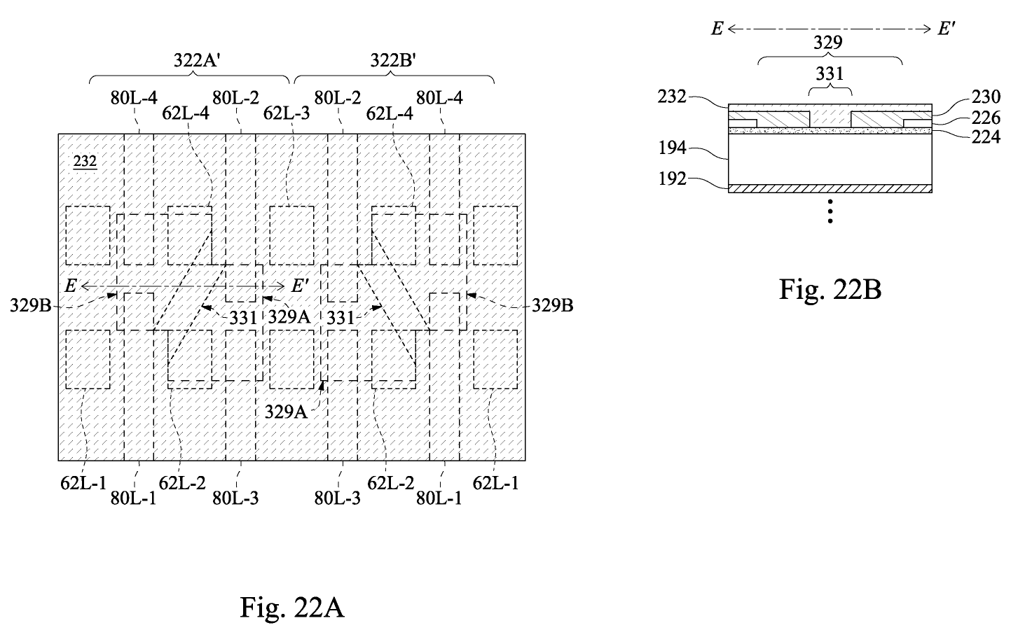

In FIGS. 22A-22B, a mask material 232 is deposited over the patterned photoresist 230 and in the openings 331, in accordance with some embodiments. The mask material 232 may be similar to the mask material 232 described previously for FIGS. 15A-15B, and may be formed using similar techniques. For example, the mask material 232 may fill the openings 331, may cover exposed surfaces of the sacrificial layer 224, and may cover surfaces of the photoresist 230.

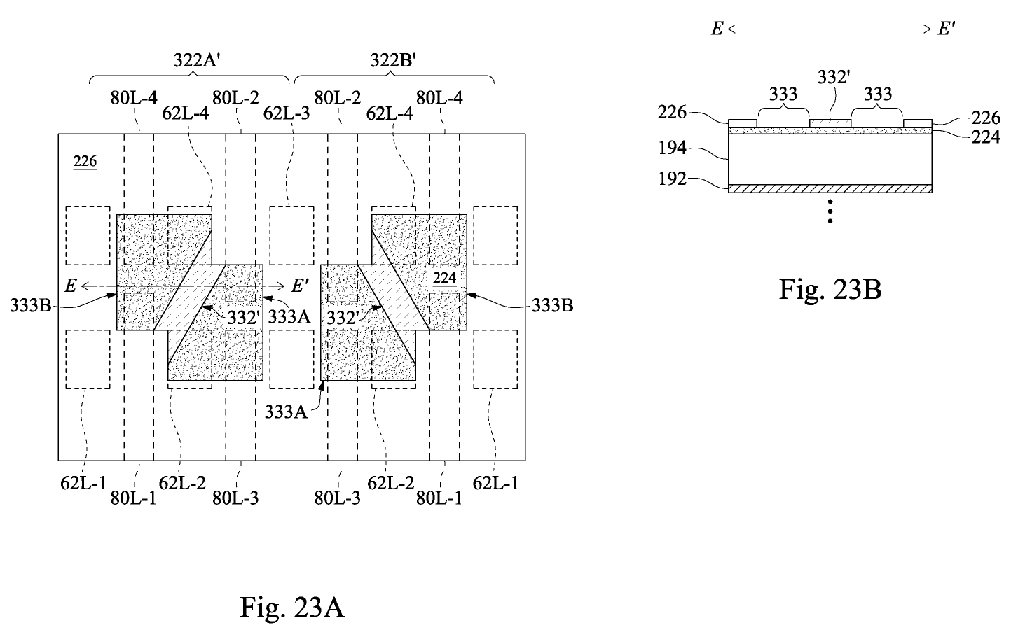

In FIGS. 23A-23B, the photoresist 230 and upper portions of the mask material 232 are removed to form cut regions 332’, in accordance with some embodiments. Similar to FIGS. 16A-16B, remaining lower portions of the mask material 232 form cut regions 332’ that separate (e.g., “cut”) each opening 329 into two openings 333. The openings 333 are used to define the subsequently-formed butted contacts 312. The photoresist 230 and the upper portions of the mask material 232 may be removed using suitable techniques, such as those described previously for FIGS. 16A-16B. Each cut region 332’ divides each opening 329 into a pair of openings 333 (e.g., openings 333A and 333B). The openings 333 may have an approximately triangular shape, as shown in FIG. 23A, though other shapes are possible. An opening 333A extends over the lower gate electrode 80L-2 and the lower epitaxial source/drain region 62L-2 of an SRAM region 322’, and the other opening 333B extends over the lower gate electrode 80L-1 and the epitaxial source/drain region 62L-4 of the same SRAM region 322’.

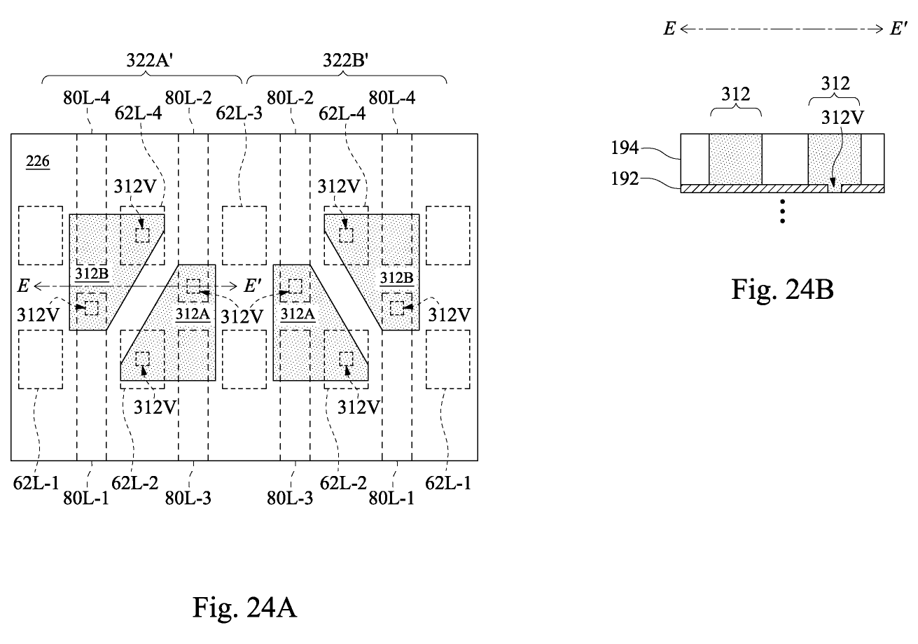

In FIGS. 24A-24B, the openings 333 are extended through the fourth ILD 194 and butted contacts 312 are formed in the openings 333, in accordance with some embodiments. The openings 333 may be extended through the sacrificial layer 224 and the fourth ILD 194 by performing one or more etch processes using the patterned hard mask 226 and the cut regions 332’ as an etch mask. In some embodiments, the openings 333 expose the ESL 192. The etch processes may include one or more suitable wet etching processes or dry etching processes, which may be anisotropic. The etch processes may be similar to those described previously for FIGS. 17A-17B. Via openings are formed through the ESL 192, in some embodiments. A liner and conductive material are then deposited in the openings 333 to form the butted contacts 312. The materials of the butted contacts 312 may be similar to those described previously for FIGS. 19A-19B. A planarization process may be performed to remove excess material. Forming butted contacts 312 using the techniques described herein can allow for higher yield and greater device density.

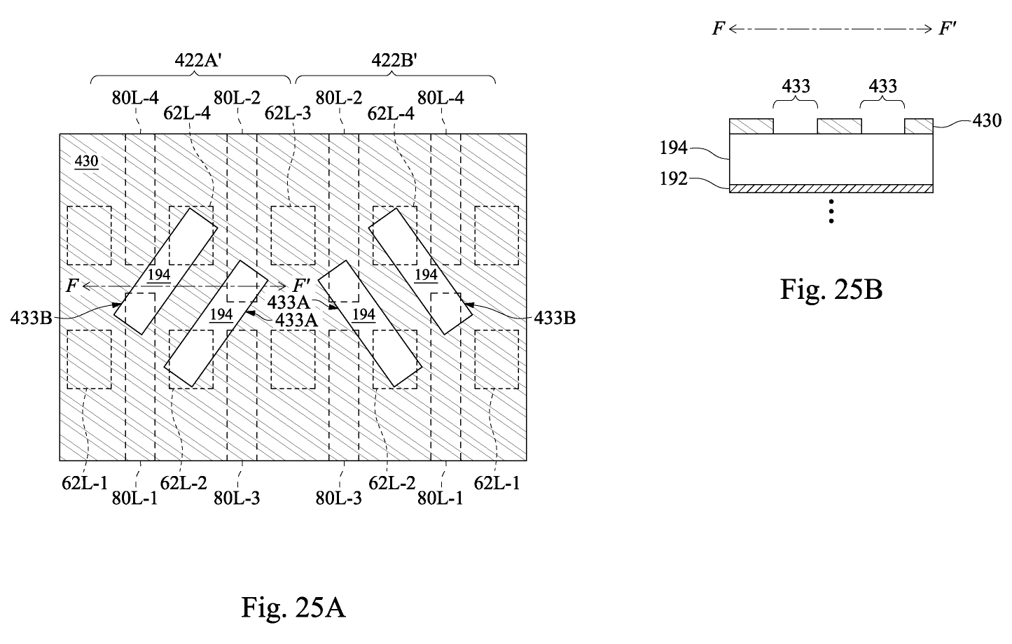

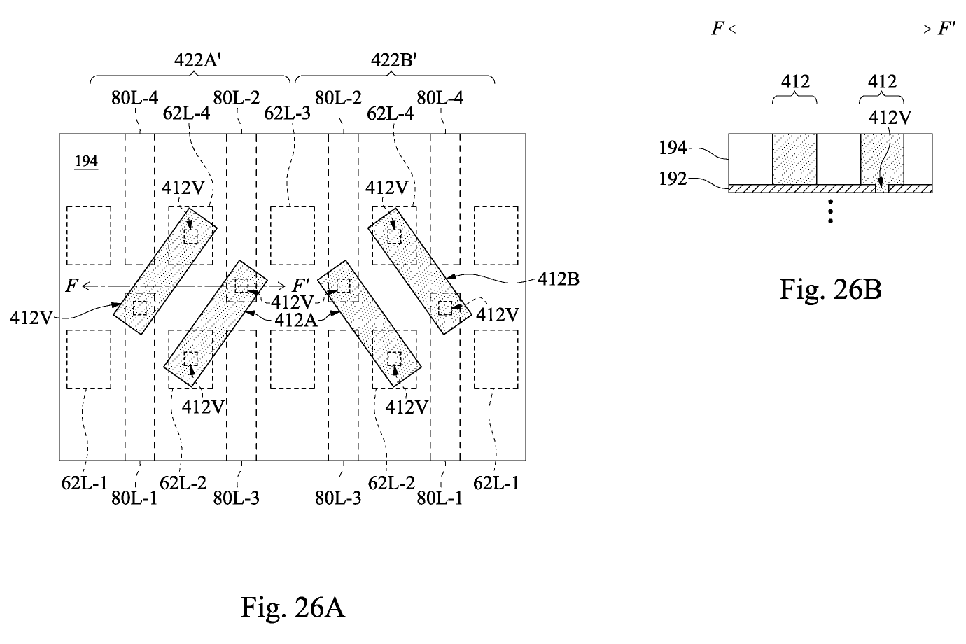

FIGS. 25A-26B illustrate intermediate steps in the formation of butted contacts 412, in accordance with some embodiments. The butted contacts 412 are similar to the butted contacts 212 described previously for FIGS. 9-10, except that the butted contacts 412 have a linear shape instead of an L-shape. Additionally, the butted contacts 412 are formed without first forming cut regions. Some of the materials or techniques are similar to those described previously for FIGS. 11A-19B, and some details are not repeated. FIGS. 25A and 26A illustrate plan views similar to the plan views of FIGS. 11A-19A, and FIGS. 25B and 26B illustrate cross-sectional views along a cross-section similar to the indicated reference cross-section F-F’.

In FIGS. 25A-25B, a photoresist 430 is formed over the fourth ILD 194 and patterned to form openings 433, in accordance with some embodiments. The photoresist 430 may be deposited using suitable techniques. The photoresist 430 may comprise a single layer or multiple layers, and may comprise a hard mask or the like. The openings 433 may be patterned using suitable photolithography techniques. In each SRAM region 422’, one opening 433B extends over a lower gate electrode 80L-1 and a lower epitaxial source/drain region 62L-4, and one opening 433A extends over a lower gate electrode 80L-2 and a lower epitaxial source/drain region 62L-2. In some embodiments, the fourth ILD 194 may extend at an angle that is slanted or oblique relative to other features, such as relative to the lower gate electrodes 80L or the semiconductor strips 20’. In some embodiments, forming the forth ILD 194 as angled and elongated shapes may improve yield and reliability of the butted contacts 412.

In FIGS. 26A-26B, the openings 433 are extended through the fourth ILD 194 and butted contacts 412 are formed in the openings 433, in accordance with some embodiments. The openings 433 may be extended through the sacrificial layer 224 and the fourth ILD 194 by performing one or more etch processes using the patterned hard mask 226 and the cut regions 332’ as an etch mask. In some embodiments, the openings 433 expose the ESL 192. The etch processes may include one or more suitable wet etching processes or dry etching processes, which may be anisotropic. The etch processes may be similar to those described previously for FIGS. 17A-17B. Via openings are formed through the ESL 192, in some embodiments. A liner and conductive material are then deposited in the openings 433 to form the butted contacts 312. The materials of the butted contacts 412 may be similar to those described previously for FIGS. 19A-19B. A planarization process may be performed to remove excess material. Forming butted contacts 412 using the techniques described herein can allow for higher yield and greater device density.

Embodiments described herein may achieve advantages. By forming butted contact in a SRAM cell using cut regions as an etch mask, smaller or closer butted contacts can be formed with improved reliability and improved yield. The butted contacts may be formed as part of a stacked transistor memory cell, such as a CFET memory cell. In some embodiments, the cut regions can be formed between neighboring memory cells, and in other embodiments, the cut regions can be formed within a memory cell. Techniques described herein allow for butted contacts having a variety of shapes, such as L-shapes, linear shapes, triangular shapes, or other shapes. The embodiments described herein can allow for greater device density, and can allow for improved physical or electrical coupling by the butted contacts.

In an embodiment of the present disclosure, a method includes forming, on a front side of a substrate, a memory structure including a first pull-up transistor, a first pull-down transistor, a first pass-gate transistor, a second pull-up transistor, a second pull-down transistor, and a second pass-gate transistor; forming a dielectric layer over a back side of the memory structure; forming a hard mask over the dielectric layer; forming a first opening in the hard mask, wherein the first opening extends over the first pull-up transistor and the second pull-up transistor; forming a mask material in the first opening, wherein the mask material separates the first opening into a second opening and a third opening; extending the second opening and third opening through the dielectric layer; and forming conductive material in the second opening to form a first butted contact and in the third opening to form a second butted contact, wherein the first butted contact electrically contacts the first pull-up transistor and the second butted contact electrically contacts the second pull-up transistor. In an embodiment, the first pull-up transistor is in a first memory cell and the second pull-up transistor is in a second memory cell adjacent the first memory cell. In an embodiment, the second opening and the third opening are L-shaped. In an embodiment, the first butted contact electrically contacts a first gate structure of the first pull-up transistor and the second butted contact electrically contacts a second gate structure of the second pull-up transistor. In an embodiment, the mask material is laterally between the first pull-up transistor and the second pull-up transistor. In an embodiment, a width between the second opening and the third opening is in the range of 10 nm to 50 nm. In an embodiment, the memory structure is a single SRAM cell. In an embodiment, the first pull-up transistor is part of a stacked transistor structure.

In an embodiment of the present disclosure, a method includes depositing a dielectric layer over a back side of a memory cell; depositing a hard mask over the dielectric layer; patterning a first opening in the hard mask, wherein the first opening extends over a first epitaxial source/drain region, a second epitaxial source/drain region, a first gate electrode, and a second gate electrode of the memory cell; depositing a photoresist over the hard mask and within the first opening; patterning a second opening in the photoresist, wherein the second opening extends across the first opening; depositing a mask material over the photoresist and within the second opening; removing the photoresist, wherein a region of mask material remains within the second opening; etching the dielectric layer using the hard mask and the region of mask material as an etch mask, wherein the etching forms recesses in the dielectric layer; and depositing conductive material in the recesses. In an embodiment, the second opening is laterally between the first epitaxial source/drain region and the second epitaxial source/drain region. In an embodiment, the second opening is laterally between the first gate electrode and the second gate electrode. In an embodiment, the recesses have a triangular shape. In an embodiment, the conductive material electrically contacts the first epitaxial source/drain region, the second epitaxial source/drain region, the first gate electrode, and the second gate electrode. In an embodiment, the region of mask material extends from one side of the first opening to a second side of the first opening. In an embodiment, the dielectric layer is deposited over an etch stop layer, and further including patterning via openings within the second opening, wherein the via openings extend through the etch stop layer.

In an embodiment of the present disclosure, a memory device includes a first lower epitaxial source/drain region adjacent a second lower epitaxial source/drain region; a first lower gate electrode adjacent a first side of the first lower epitaxial source/drain region; a second lower gate electrode adjacent a second side of the second lower epitaxial source/drain region, wherein the second side is opposite the first side; a dielectric layer under the first lower epitaxial source/drain region, the second lower epitaxial source/drain region, the first lower gate electrode, and the second lower gate electrode; a first butted contact within the dielectric layer, wherein the first butted contact electrically connects the first lower epitaxial source/drain region to the second lower gate electrode; and a second butted contact within the dielectric layer, wherein the second butted contact electrically connects the second lower epitaxial source/drain region to the first lower gate electrode. In an embodiment, the first butted contact and the second butted contact extend at oblique angles relative to the first lower gate electrode and the second lower gate electrode. In an embodiment, the first butted contact and the second butted contact have a triangular shape. In an embodiment, the memory device includes a first upper epitaxial source/drain region over the first lower epitaxial source/drain region and a first upper gate electrode over the first lower gate electrode. In an embodiment, the memory device includes a third lower gate electrode adjacent a second side of the first lower epitaxial source/drain region, wherein the first butted contact extends over the third lower gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first source/drain region and a second source/drain region, wherein the first source/drain region is adjacent the second source/drain region;
forming a first gate structure adjacent second first source/drain region and a second gate structure adjacent the first source/drain region;
depositing a first dielectric layer over the first source/drain region, the second source/drain region, the first gate structure, and the second gate structure;
forming a first mask over the first dielectric layer, wherein the first mask comprises a first opening in the first mask;
depositing a mask material over the first mask, wherein the mask material fills the first opening;
removing the first mask;
etching the first dielectric layer using the mask material as an etching mask to form a first recess and a second recess in the first dielectric layer, wherein the first recess extends over the first source/drain region and the first gate structure, wherein the second recess extends over the second source/drain region and the second gate structure; and
forming a first contact in the first recess and a second contact in the second recess.

2. The method of claim 1, further comprising, before forming the first mask, forming a second mask over the first dielectric layer, wherein the second mask comprises a second opening, wherein the first opening in the first mask is within the second opening in the second mask.

3. The method of claim 1, wherein the first mask extends over the first source/drain region, the second source/drain region, the first gate structure, and the second gate structure.

4. The method of claim 1, wherein the first recess and the second recess have triangular shapes.

5. The method of claim 1, wherein the first contact electrically connects the first source/drain region to the first gate structure and the second contact electrically connects the second source/drain region to the second gate structure.

6. The method of claim 1, further comprising forming a third source/drain region over the first source/drain region and a fourth source/drain region over the second source/drain region.

7. The method of claim 1, further comprising forming a second dielectric layer over the first gate structure, wherein the first dielectric layer extends over the second dielectric layer, wherein the first contact extends through the first dielectric layer and the second dielectric layer to contact the first gate structure.

8. The method of claim 1, further comprising depositing a sacrificial layer over the first dielectric layer, wherein the first mask is formed over the sacrificial layer.

9. A method comprising:
forming a first memory cell adjacent a second memory cell;
depositing a first mask material over the first memory cell and the second memory cell;
patterning the first mask material to form a first opening, wherein the first opening extends over a first pull-up transistor of the first memory cell, a second pull-up transistor of the first memory cell, a first pull-up transistor of the second memory cell, and a second pull-up transistor of the second memory cell;
depositing a second mask material in the first opening, wherein the second mask material is between the first memory cell and the second memory cell;
depositing a conductive material in the first opening to form a first butted contact over the first memory cell and a second butted contact over the second memory cell; and
removing the first mask material and the second mask material.

10. The method of claim 9, further comprising:
depositing a third mask material over the first mask material and in the first opening;
patterning the third mask material to form a second opening, wherein the second opening is within the first opening, wherein the second mask material fills the second opening.

11. The method of claim 9, wherein the first butted contact electrically connects the first pull-up transistor of the first memory cell to the second pull-up transistor of the first memory cell, wherein the second butted contact electrically connects the first pull-up transistor of the second memory cell to the second pull-up transistor of the second memory cell.

12. The method of claim 9, wherein the first butted contact and the second butted contact are on opposite sides of the second mask material.

13. The method of claim 9, wherein the first memory cell comprises a first pull-down transistor under the first pull-up transistor and a second pull-down transistor under the second pull-up transistor.

14. The method of claim 9, wherein the first butted contact and the second butted contact are L-shaped.

15. The method of claim 9, further comprising forming a dummy transistor between the first butted contact and the second butted contact.

16. The method of claim 9, wherein depositing the conductive material further comprises a third butted contact over a first pull-down transistor and a second pull-down transistor of the first memory cell.

17. A device comprising:
a first dielectric layer;
a first contact within the first dielectric layer, wherein the first contact extends linearly in a first direction from a first end of the first contact to a second end of the first contact;
a first lower source/drain region over the first end of the first contact, wherein the first lower source/drain region electrically contacts the first contact;
a first lower gate structure over the second end of the first contact, wherein the first lower gate structure electrically contacts the first contact;
a second lower gate structure over the first dielectric layer, wherein the second lower gate structure is adjacent to the first lower source/drain region and the first lower gate structure;
a first upper source/drain region over the first lower source/drain region; and
a first upper gate structure over the first lower gate structure.

18. The device of claim 17, wherein the second lower gate structure is free of the first contact.

19. The device of claim 17, wherein the first lower gate structure extends linearly in a second direction that is different from the first direction.

20. The device of claim 17, wherein the first lower source/drain region and the second lower gate structure contact a stack of first nanostructures.
